(19) United States
(12) Patent Application Publication
(10) Pub. No.: US 2020/0165719 A1
(43) Pub. Date: May 28, 2020

(54) SPUTTERING TARGET

(71) Applicant: SHOWA DENKO K.K., Tokyo (JP)

(72) Inventors: Takaki YASUDA, Ichihara-shi, Chiba (JP); Akira SAKAWAKI, Ichihara-shi, Chiba (JP)

(73) Assignee: SHOWA DENKO K.K., Tokyo (JP)

(21) Appl. No.: 16/604,839

(22) PCT Filed: Apr. 11, 2018
(86) PCT No.: PCT/JP2018/015186

§ 371 Date: Oct. 11, 2019

(30) Foreign Application Priority Data
Jun. 15, 2017 (JP) 2017-117616

(51) Int. Cl. C23C 14/34; H01M 4/139; H01M 4/58; H01M 10/0525; H01M 10/44

(52) U.S. Cl. CPC C23C 14/3414; H01M 4/139; H01M 10/44; H01M 10/0525; H01M 4/58

(57) ABSTRACT

The sputtering target 100 used in forming a positive electrode layer of a lithium-ion rechargeable battery is made of a sintered body including first particles 110 and second particles 120, the first particles 110 each containing lithium phosphorus oxide (e.g., Li₃PO₄) as an inorganic solid electrolyte, the second particles 120 each containing lithium transition metal oxide (e.g., LiNiO₂) as a positive electrode active material.

### TECHNICAL FIELD

The present invention relates to a sputtering target.

### BACKGROUND ART

With widespread use of portable electronics, such as mobile phones and laptop computers, a strong need exists for small and lightweight rechargeable batteries with a high energy density. Known examples of the rechargeable batteries meeting such a need include lithium-ion rechargeable batteries. The lithium-ion rechargeable battery includes a positive electrode containing a positive electrode active material, a negative electrode containing a negative electrode active material, and an electrolyte exhibiting lithium ionic conductivity and disposed between the positive electrode and the negative electrode.

Considerations have been given to forming the lithium-ion rechargeable battery of a stacked structure of thin films, and among methods for forming such films, a sputtering method has been a focus of attention.

Patent Literature 1 discloses using a sputtering target made of an LiNiO₂ sintered body to form an LiNiO₂ film as a positive electrode material of the lithium-ion rechargeable battery.

As a positive electrode of the lithium-ion rechargeable battery, use of a composite electrode has also been proposed. The composite electrode includes, for example, a positive electrode active material and a solid electrolyte.

Patent Literature 2 discloses co-sputtering Li₃PO₄ and Ni as sputtering targets to form an LiₓNi_{y}PO_{z} film as a positive electrode active material film of the lithium-ion rechargeable battery.

### CITATION LIST

### Patent Literature

Patent Document 1: Japanese Patent Application Laid-Open Publication No. 2016-023333

Patent Document 2: Japanese Patent Application Laid-Open Publication No. 2013-164971

### SUMMARY OF INVENTION

### Technical Problem

When the composite electrode is used as a positive electrode of the lithium-ion rechargeable battery, co-sputtering multiple sputtering targets requires setting different sputtering conditions for each of the sputtering targets. This may result in variation of composition and the like in the composite electrodes obtained by the sputtering.

An object of the present invention is to enable sputtering formation of the composite electrode without use of multiple sputtering targets having different compositions and the like.

### Solution to Problem

The present invention relates to a sputtering target used in forming a positive electrode of a lithium-ion rechargeable battery, and the sputtering target is made of a sintered body containing lithium, transition metal, phosphorus, and oxygen.

In the sputtering target, the transition metal may be at a higher molar ratio to the phosphorus.

Further, the lithium may be at a higher molar ratio to the transition metal.

From another aspect, the present invention relates to a sputtering target used in forming a positive electrode of a lithium-ion rechargeable battery, and the sputtering target is made of a sintered body including first particles and second particles. The first particles mainly contain lithium phosphorus oxide. The second particles mainly contain lithium transition metal oxide.

The sputtering target may contain a larger amount of the lithium transition metal oxide than the lithium phosphorus oxide in terms of molar ratio.

Further, a particle size of each of the first particles may be larger than a particle size of each of the second particles.

### Advantageous Effects of Invention

The present invention enables sputtering formation of the composite electrode without use of multiple sputtering targets having different compositions and the like.

### BRIEF DESCRIPTION OF DRAWINGS

FIG. 1 depicts an overview of a sputtering target according to the present embodiment.

FIG. 2 depicts a sectional structure of a lithium-ion rechargeable battery.

FIGS. 3A and 3B depict specific capacity—voltage characteristics of positive electrode layers of Example and Comparative Example, respectively.

FIGS. 4A and 4B depict relationship between a charge/discharge rate and a capacity ratio in Example and Comparative Example.

### DESCRIPTION OF EMBODIMENTS

Embodiments of the present invention will be described in detail below with reference to the attached drawings. In the drawings as referred to in the below description, dimensions of each component, including size and thickness, may differ from actual ones.

### [Structure of the Sputtering Target]

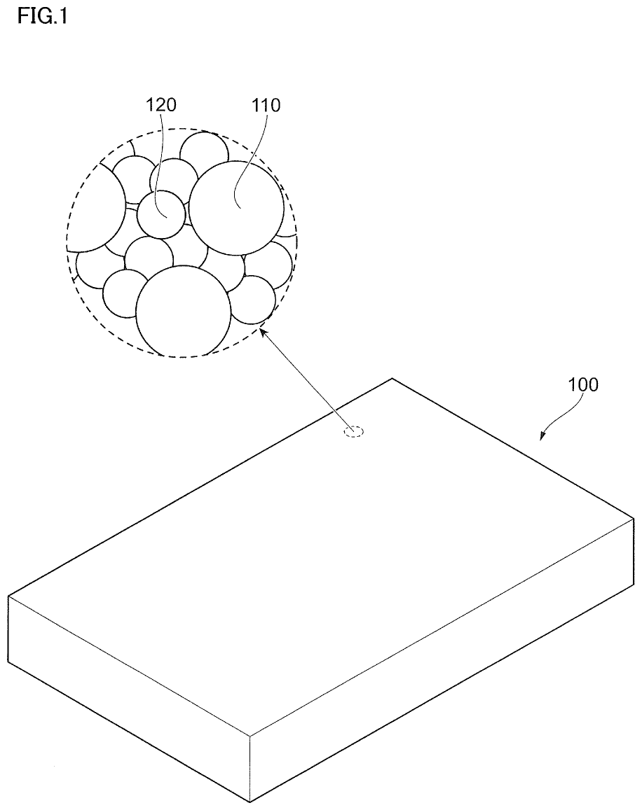

FIG. 1 depicts an overview of a sputtering target 100 according to the present embodiment.

The sputtering target 100 is made of a sintered body obtained by sintering raw powders (in the present embodiment, oxide powders). In this example, the sputtering target 100 has a rectangular and planar shape. The sputtering target 100 includes multiple first particles 110 each mainly containing an inorganic solid electrolyte and multiple second particles 120 each mainly containing a positive electrode active material. The particle size of each of the first particles 110 and the second particles 120 is 0.2 μm to 5.0 μm, and mainly 0.5 μm to 1.0 μm.

From another standpoint, the sputtering target 100 of the present embodiment is made of a sintered body containing lithium, transition metal, phosphorus, and oxygen. In the sputtering target 100, the transition metal is at a higher molar ratio to phosphorus. Examples of the transition metal include titanium (Ti), zirconium (Zr), hafnium (Hf), vanadium (V), niobium (Nb), tantalum (Ta), chromium (Cr), molybdenum (Mo), tungsten (W), manganese (Mn), iron (Fe), ruthenium (Ru), cobalt (Co), and nickel (Ni). Besides the transition metal, the sputtering target 100 may further contain copper (Cu), silver (Ag), zinc (Zn), cadmium (Cd), Aluminum (Al) and the like.

### (First Particles)

In this example, the first particles 110 are made of lithium phosphorus oxide mainly containing lithium, phosphorus, and oxygen. More specifically, the first particles 110 of the present embodiment contain lithium phosphate (Li₃PO₄) as an example of the lithium phosphorus oxide.

### (Second Particles)

In this example, the second particles 120 are made of lithium transition metal oxide mainly containing lithium, transition metal, phosphorus, and oxygen. More specifically, the second particles 120 of the present embodiment contain lithium nickelate (LiNiO₂) as an example of the lithium transition metal oxide.

### (Relationship Between Lithium Phosphorus Oxide and Lithium Transition Metal Oxide)

In terms of molar ratio, the sputtering target 100 of the present embodiment contains a larger amount of the lithium transition metal oxide, which constitutes the second particles 120, than the lithium phosphorus oxide, which constitutes the first particles 110.

### (Relationship Between the First Particles and the Second Particles)

In the sputtering target 100 of the present embodiment, the particle size of each of the first particles 110 is larger than that of each of the second particles 120.

### [Structure of the Lithium-Ion Rechargeable Battery]

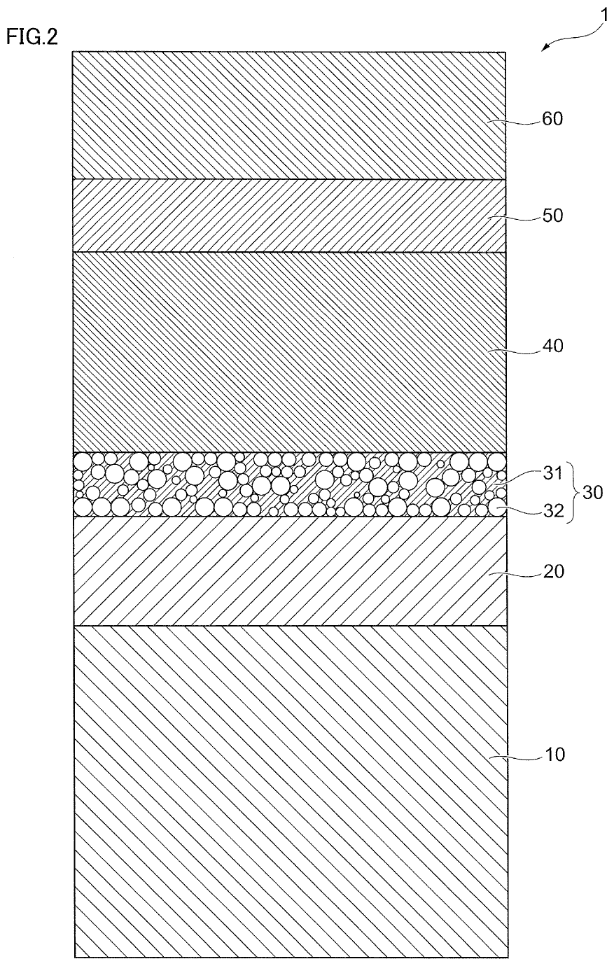

FIG. 2 depicts a sectional structure of an lithium-ion rechargeable battery 1.

The lithium-ion rechargeable battery 1 includes: a substrate 10; a positive electrode collector layer 20 stacked on the substrate 10; a positive electrode layer 30 stacked on the positive electrode collector layer 20; an inorganic solid electrolyte layer 40 stacked on the positive electrode layer 30; a negative electrode layer 50 stacked on the inorganic solid electrolyte layer 40; and a negative electrode collector layer 60 stacked on the negative electrode layer 50. The sputtering target 100 shown in FIG. 1 is used for manufacture of the positive electrode layer 30, which will be described in detail later.

The above constituents of the lithium-ion rechargeable battery 1 of the present embodiment will be described in more detail below.

### (Substrate)

The substrate 10 is not limited to a particular material, and may be made of any of various materials including metal, glass, ceramics, and resin.

In the present embodiment, the substrate 10 is made of resin. Examples of the materials that can be used for the substrate 10 include polycarbonate (PC) fluororesin, polyethylene terephthalate (PET), polybutylene terephthalate (PBT), polyimide (PI), polyamide (PA), polysulfone (PSF), polyether sulfone (PES), polyphenylene sulfide (PPS), polyetheretherketone (PEEK), polyethylene naphthalate (PEN), and cyclo olefin polymer (COP). Desirably, the substrate 10 is made of a material with low hygroscopicity and high moisture resistance.

### (Positive Electrode Collector Layer)

The positive electrode collector layer 20 may be a solid thin film having electron conductivity. As long as these conditions are met, the positive electrode collector layer 20 is not limited to a particular material, and may be made of, for example, a conductive material including metals such as titanium (Ti), aluminum (Al), copper (Cu), platinum (Pt) and gold (Au) and alloy of these metals.

The positive electrode collector layer 20 may have a thickness of 5 nm or more and 50 μm or less. With a thickness of less than 5 nm, the positive electrode collector layer 20 reduces its current collection capability, which makes the lithium-ion rechargeable battery 1 impracticable. With a thickness of more than 50 μm, it takes too much time to form the positive electrode collector layer 20 despite no large change in electrical characteristics, and this reduces productivity.

### (Positive Electrode Layer)

The positive electrode layer 30 is a solid thin film and contains a positive electrode active material that releases lithium ions during a charge and occludes lithium ions during a discharge, and a solid electrolyte made of an inorganic material (inorganic solid electrolyte). This means that the positive electrode layer 30 of the present embodiment is formed of a composite electrode containing the positive electrode active material and the inorganic solid electrolyte. The positive electrode layer 30 of the present embodiment includes a solid electrolyte region 31 mainly containing the solid electrolyte and a positive electrode region 32 mainly containing the positive electrode active material. In the positive electrode layer 30, the solid electrolyte constituting the solid electrolyte region 31 and the positive electrode active material constituting the positive electrode region 32 are present while maintaining their form. As a result, one of these substances serves as a matrix (base material) and the other serves as a filler in the positive electrode layer 30.

The positive electrode layer 30 may have a thickness of 10 nm or more and 100 μm or less, for example. With the positive electrode layer 30 having a thickness of less than 10 nm, the lithium-ion rechargeable battery 1 obtained therefrom has a too small capacity, which makes the lithium-ion rechargeable battery 1 impracticable. Meanwhile, with the positive electrode layer 30 having a thickness of more than 100 μm, it takes too much time to form the layer, which reduces productivity. The positive electrode layer 30 may, however, have a thickness of more than 100 μm when a large battery capacity is required of the lithium-ion rechargeable battery 1.

### [Solid Electrolyte Region]

The solid electrolyte region 31 mainly contains the inorganic solid electrolyte. Examples of the inorganic solid electrolyte constituting the solid electrolyte region 31 include one made of lithium phosphorus oxide.

### [Positive Electrode Region]

The positive electrode region 32 mainly contains the positive electrode active material. Examples of the positive electrode active material constituting the positive electrode region 32 include one made of lithium transition metal oxide.

### [Relationship Between the Solid Electrolyte Region and the Positive Electrode Region]

In the positive electrode layer 30 of the present embodiment, the inorganic solid electrolyte in the solid electrolyte region 31 is preferably non-crystalline, and the positive electrode active material in the positive electrode region 32 is preferably crystalline.

Also, in the positive electrode layer 30 of the present embodiment, the solid electrolyte region 31 containing the inorganic solid electrolyte is preferably the matrix (base material), and the positive electrode region 32 containing the positive electrode active material is preferably the filler (particles) dispersed in the matrix.

It is desirable that the solid electrolyte region 31 constituting the positive electrode layer 30 have the same composition as the first particles 110 in the sputtering target 100. Also, it is desirable that the positive electrode region 32 constituting the positive electrode layer 30 have the same composition as the second particles 120 in the sputtering target 100.

### (Inorganic Solid Electrolyte Layer)

The inorganic solid electrolyte layer 40 is a solid thin film and contains a solid electrolyte made of an inorganic material (inorganic solid electrolyte). The inorganic solid electrolyte constituting the inorganic solid electrolyte layer 40 is not limited to a particular material as long as the inorganic solid electrolyte exhibits lithium ionic conductivity, and may be made of any of various materials including oxide, nitride, and sulfide. However, it is desirable that the inorganic solid electrolyte constituting the inorganic solid electrolyte layer 40 contain the same element as that of the solid electrolyte constituting the solid electrolyte region 31 in the above positive electrode layer 30. For example, when the solid electrolyte region 31 of the positive electrode layer 30 is made of Li₃PO₄, the inorganic solid electrolyte layer 40 may be made of Li₃PO₄ similarly to the solid electrolyte region 31 or may be made of LiPON, which further contains nitrogen.

The inorganic solid electrolyte layer 40 may have a thickness of 10 nm or more and 10 μm or less, for example. With the inorganic solid electrolyte layer 40 having a thickness of less than 10 nm, the lithium-ion rechargeable battery 1 obtained therefrom is prone to a short circuit (leakage) between the positive electrode layer 30 and the negative electrode layer 50. Meanwhile, with the inorganic solid electrolyte layer 40 having a thickness of more than 10 μm, the migration distance of lithium ions is lengthened, which leads to a slower charge and discharge speed.

### (Negative Electrode Layer)

The negative electrode layer 50 is a solid thin film and contains a negative electrode active material that occludes lithium ions during a charge and releases lithium ions during a discharge. Examples of the negative electrode active material constituting the negative electrode layer 50 include carbon and silicon. The negative electrode layer 50 may be doped with various dopants.

The negative electrode layer 50 may have a thickness of 10 nm or more and 40 μm or less, for example. With the negative electrode layer 50 having a thickness of less than 10 nm, the lithium-ion rechargeable battery 1 obtained therefrom has a too small capacity, which makes the lithium-ion rechargeable battery 1 impracticable. Meanwhile, with the negative electrode layer 50 having a thickness of more than 40 μm, it takes too much time to form the layer, which reduces productivity. The negative electrode layer 50 may, however, have a thickness of more than 40 μm when a large battery capacity is required of the lithium-ion rechargeable battery 1.

### (Negative Electrode Collector Layer)

The negative electrode collector layer 60 may be a solid thin film having electron conductivity. As long as these conditions are met, the negative electrode collector layer 60 is not limited to a particular material, and may be made of, for example, a conductive material including metals such as titanium (Ti), aluminum (Al), copper (Cu), platinum (Pt) and gold (Au) and alloy of these metals.

The negative electrode collector layer 60 may have a thickness of 5 nm or more and 50 μm or less. With a thickness of less than 5 nm, the negative electrode collector layer 60 reduces its current collection capability, which makes the lithium-ion rechargeable battery 1 impracticable. With a thickness of more than 50 μm, it takes too much time to form the negative electrode collector layer 60 despite no large change in electrical characteristics, and this reduces productivity.

### [Operation of the Lithium-Ion Rechargeable Battery]

When the lithium-ion rechargeable battery 1 in a discharged state is charged, a positive electrode of a DC power source is connected to the positive electrode collector layer 20 and a negative electrode of the DC power source is connected to the negative electrode collector layer 60. Then, lithium ions constituting the positive electrode active material in the positive electrode layer 30 move through the inorganic solid electrolyte layer 40 to the negative electrode layer 50, where the lithium ions are accommodated in the negative electrode active material.

When the lithium-ion rechargeable battery 1 in a charged state is used (discharged), a positive side of the load is connected to the positive electrode collector layer 20 and a negative side of the load is connected to the negative electrode collector layer 60. Then, the lithium ions accommodated in the negative electrode active material in the negative electrode layer 50 move through the inorganic solid electrolyte layer 40 to the positive electrode layer 30, where the lithium ions constitute the positive electrode active material. Along with this, a direct current is supplied to the load.

### [Method for Manufacturing the Lithium-Ion Rechargeable Battery]

Here, a description will be given of a method for manufacturing the lithium-ion rechargeable battery 1 of the present embodiment.

In the present embodiment, the positive electrode collector layer 20, the positive electrode layer 30, the inorganic solid electrolyte layer 40, the negative electrode layer 50, and the negative electrode collector layer 60 are stacked in this order on the substrate 10 using a sputtering method. In stacking (depositing) the positive electrode layer 30 on the positive electrode collector layer 20 stacked on the substrate 10, the sputtering target 100 shown in FIG. 1 is used.

### [Others]

While the sputtering target 100 of the present embodiment is rectangular, the sputtering target 100 is not limited to this shape and may have any other shape (e.g., round shape).

In the present embodiment, the positive electrode collector layer 20, the positive electrode layer 30, the inorganic solid electrolyte layer 40, the negative electrode layer 50, and the negative electrode collector layer 60 are stacked in this order on the substrate 10 using the sputtering method to manufacture the lithium-ion rechargeable battery 1. However, the method for manufacturing the lithium-ion rechargeable battery 1 is not limited to this; the negative electrode collector layer 60, the negative electrode layer 50, the inorganic solid electrolyte layer 40, the positive electrode layer 30, and the positive electrode collector layer 20 may be stacked in this order on the substrate 10 using the sputtering method. In this case, the positive electrode layer 30 is formed on the inorganic solid electrolyte layer 40 using the sputtering target 100.

When the sputtering target 100 made of the inorganic solid electrolyte is used for sputtering, an RF sputtering method should be used because of a low electron conductivity of the inorganic solid electrolyte. This may make it impossible to increase a formation speed of the positive electrode layer 30 (composite electrode). In the present embodiment, however, the sputtering target 100 containing not only the inorganic solid electrolyte but also the positive electrode active material, which has a high electron conductivity, is used. This allows for formation of the positive electrode layer 30 (composite electrode) using a DC sputtering method, which makes it possible to increase the formation speed of the positive electrode layer 30 (composite electrode).

### EXAMPLES

The present invention will be described in more detail below based on Example. It should be noted that the present invention is not limited to Example given below as long as its scope is not exceeded.

The present inventors fabricated multiple lithium-ion rechargeable batteries 1 while varying the constitution of the sputtering targets 100 used for formation of the respective positive electrode layers 30. The present inventors then evaluated the thus-obtained lithium-ion rechargeable batteries 1 in regard to the crystalline structure and the specific capacity of each positive electrode layer 30.

Table 1 and Table 2 show the constitution of each layer of the lithium-ion rechargeable battery 1 of Example and Comparative Example, respectively.

| EXAMPLE | CONSTITUTION | | | |
|---|---|---|---|---|
| MEMBER | MATERIAL | THICKNESS | | STRUCTURE |
| NEGATIVE ELECTRODE | Ti | 350 | nm | CRYSTALLINE |
| COLLECTOR LAYER | (TARGET) | | | |
| NEGATIVE ELECTRODE | Si(B) | 200 | nm | NON-CRYSTAL LINE |
| LAYER | (TARGET) | | | |
| INORGANIC SOLID | LiPON | 550 | nm | NON-CRYSTALLINE |
| ELECTROLYTE LAYER | (TARGET) | | | |
| POSITIVE ELECTRODE | Li_{7.0}Ni_{4.0}P_{1.0}O_{12.0} | 175 | nm | CRYSTALLINE + |
| LAYER | (TARGET) | | | NON-CRYSTALLINE |
| POSITIVE ELECTRODE | Ti | 300 | nm | CRYSTALLINE |
| COLLECTOR LAYER | (TARGET) | | | |
| SUBSTRATE | PC | 1.1 | mm | — |

TABLE 2

| COMPARATIVE | | | | |
|---|---|---|---|---|
| EXAMPLE | CONSTITUTION | | | |
| MEMBER | MATERIAL | THICKNESS | | STRUCTURE |
| NEGATIVE ELECTRODE | Ti | 350 | nm | CRYSTALLINE |
| COLLECTOR LAYER | (TARGET) | | | |
| NEGATIVE ELECTRODE | Si(B) | 200 | nm | NON-CRYSTAL LINE |
| LAYER | (TARGET) | | | |
| INORGANIC SOLID | LiPON | 550 | nm | NON-CRYSTALLINE |
| ELECTROLYTE LAYER | (TARGET) | | | |
| POSITIVE ELECTRODE | Li_{7.0}Ni_{7.0}P₀₀O_{14.0} | 175 | nm | CRYSTALLINE |
| LAYER | (LiNiO₂) | | | |
| | (TARGET) | | | |
| POSITIVE ELECTRODE | Ti | 300 | nm | CRYSTALLINE |
| COLLECTOR LAYER | (TARGET) | | | |
| SUBSTRATE | PC | 1.1 | mm | — |

### Example

In Example, polycarbonate (PC) was used as the substrate 10. The thickness of the substrate 10 was 1.1 mm.

In Example, the positive electrode collector layer 20 was formed using the sputtering method. In forming the positive electrode collector layer 20, titanium (Ti) was used as a sputtering target (described as “target” in the tables; the same applies below). The thickness of the positive electrode collector layer 20 was 300 nm.

In Example, the positive electrode layer 30 was formed using the sputtering method. In forming the positive electrode layer 30, a sintered body containing lithium (Li), nickel (Ni), phosphorus (P), and oxygen (O) was used as the sputtering target 100 shown in FIG. 1. In Example, the composition of the sputtering target 100 was Li_{7.0}Ni_{4.0}P_{1.0}O_{12.0}. The thickness of the positive electrode layer 30 was 175 nm. The composition (Li_{7.0}Ni_{4.0}P_{1.0}O_{12.0}) of the sputtering target 100 used in Example can be expressed as “Li₃PO₄+4LiNiO₂ (Li₄Ni₄O₈)”.

The sputtering target 100 used in Example was observed by an SEM (scanning electron microscope). The observation showed that particles with the particle size of about 1 μm and particles with the particle size of about several μm were present. The sputtering target 100 was also analyzed with EDX (energy dispersive X-ray spectrometry). The analysis showed that the relatively large particles (with the particle size of about several μm) were the first particles 110 mainly containing lithium phosphorus oxide, and the relatively small particles (with the particle size of about 1 μm) were the second particles 120 mainly containing lithium transition metal oxide.

In Example, the inorganic solid electrolyte layer 40 was formed using the sputtering method. In forming the inorganic solid electrolyte layer 40, LiPON (LiₐPO_{b}N_{c}) obtained by replacing a portion of oxygen in Li₃PO₄ with nitrogen was used as a sputtering target. The thickness of the inorganic solid electrolyte layer 40 was 550 nm.

In Example, the negative electrode layer 50 was formed using the sputtering method. In forming the negative electrode layer 50, boron (B)-doped silicon (Si) was used as a sputtering target (described as “Si (B)” in the tables; the same applies below). The thickness of the negative electrode layer 50 was 200 nm.

In Example, the negative electrode collector layer 60 was formed using the sputtering method. In forming the negative electrode collector layer 60, titanium (Ti) was used as the sputtering target. The thickness of the negative electrode collector layer 60 was 350 nm.

### Comparative Example

The lithium-ion rechargeable battery 1 of Comparative Example was manufactured under the same conditions as those in Example, except for the conditions regarding the sputtering target 100 used for formation of the positive electrode layer 30. Accordingly, detailed description of the substrate 10, the positive electrode collector layer 20, the inorganic solid electrolyte layer 40, the negative electrode layer 50, and the negative electrode collector layer 60 in Comparative Example will be omitted.

In Comparative Example, the positive electrode layer 30 was formed using the sputtering method. In forming the positive electrode layer 30, a sintered body containing lithium (Li), nickel (Ni), and oxygen (O) but not containing phosphorus (P) was used as the sputtering target 100 shown in FIG. 1. In Comparative Example, the composition of the sputtering target 100 was Li_{7.0}Ni_{7.0}P_{0.0}O_{14.0} (═LiNiO₂). The thickness of the positive electrode layer 30 was 175 nm.

### [Evaluation of the Lithium-Ion Rechargeable Batteries]

As a measure to evaluate the lithium-ion rechargeable batteries 1 of Example and Comparative Example, the crystalline structure of each lithium-ion rechargeable battery 1 and capacity of the positive electrode layer 30 of each lithium-ion rechargeable battery 1 were used.

### (Crystalline Structure)

First, referring to Table 1, the crystalline structure of the lithium-ion rechargeable battery 1 of Example will be described.

In the lithium-ion rechargeable battery 1 of Example, the positive electrode collector layer 20 was crystalline. Also, a crystalline region and a non-crystalline region were both present in the positive electrode layer 30. The crystalline region was the positive electrode region 32 mainly containing LiNiO₂, which is a positive electrode active material, and the non-crystalline region was the solid electrolyte region 31 mainly containing Li₃PO₄, which is an inorganic solid electrolyte. Also, both of the inorganic solid electrolyte layer 40 and the negative electrode layer 50 were non-crystalline, and the negative electrode collector layer 60 was crystalline.

Then, referring to Table 2, the crystalline structure of the lithium-ion rechargeable battery 1 of Comparative Example will be described. In the lithium-ion rechargeable battery 1 of Comparative Example, the positive electrode collector layer 20 was crystalline. The positive electrode layer 30 was also crystalline. The crystalline region in the positive electrode layer 30 was the positive electrode region 32 mainly containing LiNiO₂, which is a positive electrode active material. Also, both of the inorganic solid electrolyte layer 40 and the negative electrode layer 50 were non-crystalline, and the negative electrode collector layer 60 was crystalline.

### (Specific Capacity)

The positive electrode layers 30 of the respective lithium-ion rechargeable batteries 1 of Example and Comparative Example were evaluated in terms of specific capacity. The specific capacity of the positive electrode layer 30 refers to a capacity of the positive electrode active material per unit mass.

For evaluation of the specific capacity, charge/discharge characteristics of the lithium-ion rechargeable batteries 1 were measured. As an instrument to measure the charge/discharge characteristics, HJ1020mSD8 charge-discharge device from Hokuto Denko Corporation was used.

The lithium-ion rechargeable batteries 1 of Example and Comparative Example were charged under a constant current-constant voltage (CCCV) mode. End-of-charge voltage was 4.2 V.

Also, the lithium-ion rechargeable batteries 1 of Example and Comparative Example were discharged under a constant current (CC) mode. End-of-discharge voltage was 0.5 V.

The lithium-ion rechargeable battery 1 of Example was charged and discharged under the three conditions of 0.8C, 1.6C, and 3.1C. Meanwhile, the lithium-ion rechargeable battery 1 of Comparative Example was charged and discharged under the three conditions of 0.9C, 1.8C and 3.6C. Here, “C” refers to an electric current value with which discharge of cells having a given nominal capacity value is completed in one hour when the cells are discharged at constant current. For example, 1C=3.5 A for the cells having a nominal capacity value of 3.5 Ah. Hereinafter, this may be referred to as a charge/discharge rate.

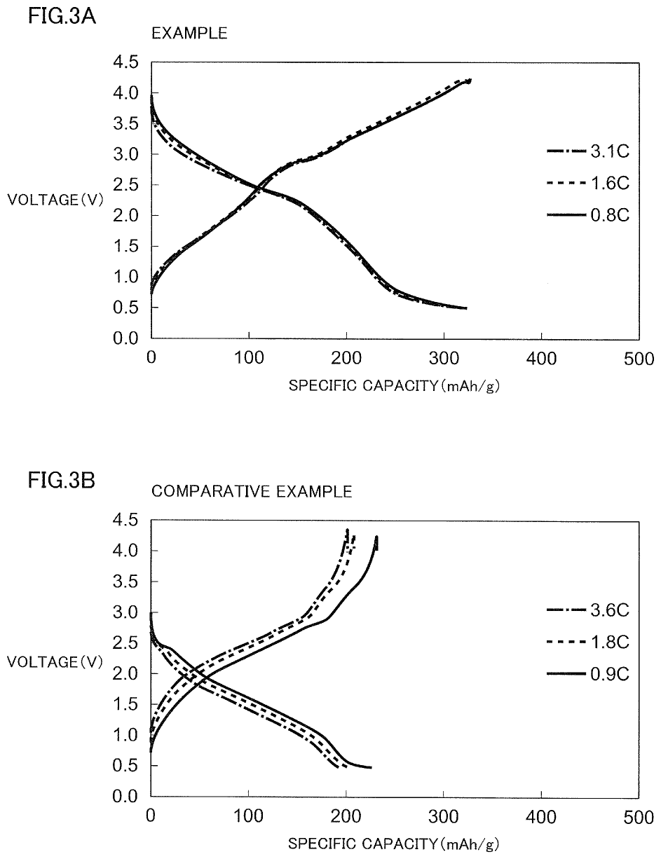

FIGS. 3A and 3B depict specific capacity—voltage characteristics of the positive electrode layers 30 of Example and Comparative Example, respectively. FIG. 3A shows the results of Example, and FIG. 3B shows the results of Comparative Example. In each of FIGS. 3A and 3B, the horizontal axis represents the specific capacity (mAh/g) of the positive electrode layer 30, and the vertical axis represents the voltage (V), which means an electrode potential of the positive electrode layer 30.

As can be seen in FIGS. 3A and 3B, the positive electrode layer 30 of Example has a larger specific capacity than the positive electrode layer 30 of Comparative Example. This means that, in terms of the specific capacity, it is more preferable to manufacture the positive electrode layer 30 with the sputtering target 100 containing lithium (Li), nickel (Ni), phosphorus (P), and oxygen (O) than to manufacture the positive electrode layer 30 with the sputtering target 100 containing Li, Ni, and O but not containing P.

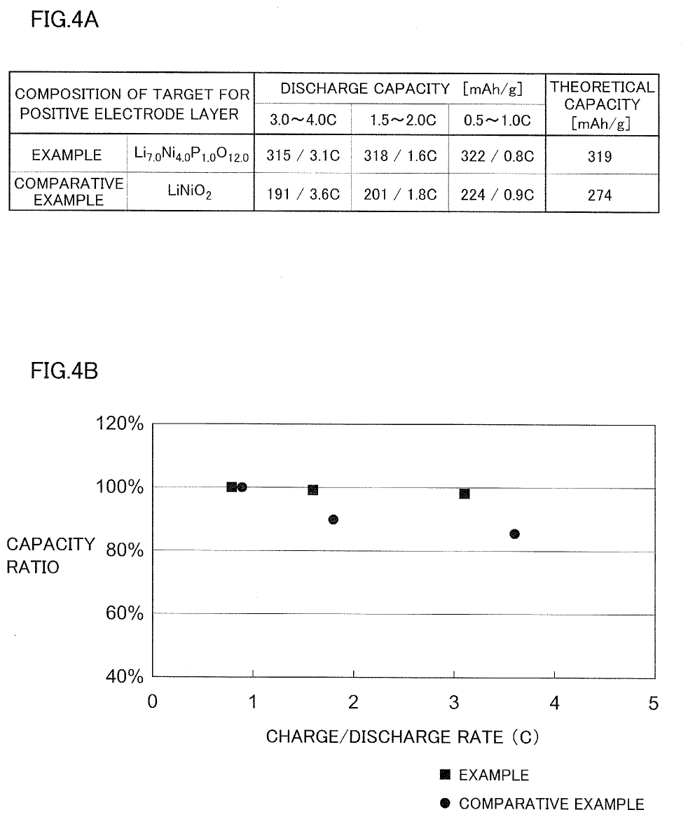

FIGS. 4A and 4B depict relationship between a charge/discharge rate and a capacity ratio in Example and Comparative Example. FIG. 4A depicts an actual discharge capacity and a theoretical capacity of the positive electrode layers 30 of Example and Comparative Example. FIG. 4B depicts charge/discharge rate—capacity ratio characteristics of the positive electrode layers 30 of Example and Comparative Example. The capacity ratio on the vertical axis of FIG. 4B represents a value obtained by dividing each discharge capacity of each positive electrode layer 30 by the discharge capacity at each minimum charge/discharge rate (0.8C in Example and 0.9C in Comparative Example), namely represents the ratio of discharge capacity.

First, referring to FIG. 4A, theoretical capacities of the positive electrode layers 30 of Example and Comparative Example will be compared.

In Example, the theoretical capacity of the positive electrode layer 30 was 319 (mAh/g). In Comparative Example, the theoretical capacity of the positive electrode layer 30 was 274 (mAh/g). This means that the theoretical capacity of the positive electrode layer 30 of Comparative Example is smaller than that of the positive electrode layer 30 of Example.

Then, referring to FIG. 4A, actual discharge capacities of the positive electrode layers 30 of Example and Comparative Example will be compared.

In Example, the discharge capacity was 315 (mAh/g) at the charge/discharge rate of 3.1C, 318 (mAh/g) at the charge/discharge rate of 1.6C, and 322 (mAh/g) at the charge/discharge rate of 0.8C. In Comparative Example, the discharge capacity was 191 (mAh/g) at the charge/discharge rate of 3.6C, 201 (mAh/g) at the charge/discharge rate of 1.8C, and 224 (mAh/g) at the charge/discharge rate of 0.9C.

Then, referring to FIG. 4B, the relationship between the charge/discharge rate and the capacity ratio of each of the positive electrode layers 30 of Example and Comparative Example will be described.

In Example, the capacity ratio is stable at nearly 100% regardless of whether the charge/discharge rate is high or low. On the other hand, in Comparative Example, the capacity ratio decreases with increase in the charge/discharge rate.

### REFERENCE SIGNS LIST

1 Lithium-ion rechargeable battery
10 Substrate
20 Positive electrode collector layer
30 Positive electrode layer
31 Solid electrolyte region
32 Positive electrode region
40 Inorganic solid electrolyte layer
50 Negative electrode layer
60 Negative electrode collector layer
100 Sputtering target
110 First particle
120 Second particle

1.-6. (canceled)

7. A sputtering target used in forming a positive electrode of a lithium-ion rechargeable battery, the sputtering target comprising:
a sintered body containing lithium, transition metal, phosphorus, and oxygen.

8. The sputtering target according to claim 7, wherein the transition metal is at a higher molar ratio to the phosphorus.

9. The sputtering target according to claim 7, wherein the lithium is at a higher molar ratio to the transition metal.

10. The sputtering target according to claim 8, wherein the lithium is at a higher molar ratio to the transition metal.

11. A sputtering target used in forming a positive electrode of a lithium-ion rechargeable battery, the sputtering target comprising:
a sintered body including first particles and second particles, the first particles mainly containing lithium phosphorus oxide, the second particles mainly containing lithium transition metal oxide.

12. The sputtering target according to claim 11, wherein the sputtering target contains a larger amount of the lithium transition metal oxide than the lithium phosphorus oxide in terms of molar ratio.

13. The sputtering target according to claim 11, wherein a particle size of each of the first particles is larger than a particle size of each of the second particles.

14. The sputtering target according to claim 12, wherein a particle size of each of the first particles is larger than a particle size of each of the second particles.
